(19) United States
(12) Patent Application Publication
(10) Pub. No.: US 2025/0185401 A1
(43) Pub. Date: Jun. 5, 2025

(54) PHOTOELECTRIC CONVERSION DEVICE AND EQUIPMENT

(71) Applicant: CANON KABUSHIKI KAISHA, Tokyo (JP)

(72) Inventor: HIROSHI SEKINE, Kanagawa (JP)

(21) Appl. No.: 18/947,223

(22) Filed: Nov. 14, 2024

(30) Foreign Application Priority Data
Dec. 4, 2023 (JP) 2023-204914

(51) Int. Cl. H01L 27/146; H01L 23/00

(52) U.S. Cl. CPC H10F 39/809; H01L 24/08; H10F 39/811; H01L 2224/08145

(57) ABSTRACT

A device in which a first semiconductor including first and second floating diffusions, a first structure, a second structure and a second semiconductor are stacked in this order is provided. The first and second structures are bonded with metal pads including first and second pads and third pad arranged between the first and second pads. First and second transistors are arranged on a side of the second semiconductor opposite to the first semiconductor, the first floating diffusion is connected to the first transistor via the first pad, the second floating diffusion is connected to the second transistor via the second pad, and a conductive pattern extending toward the first semiconductor from the third pad. Wiring patterns connecting the first pad and the first transistor and connecting the second pad and the second transistor are arranged to extend through the second semiconductor.

### BACKGROUND OF THE INVENTION

### Field of the Invention

The present invention relates to a photoelectric conversion device and equipment.

### Description of the Related Art

Japanese Patent Laid-Open No. 2023-110873 describes an image sensor in which the first structure including the first substrate and the second structure including the second substrate are stacked. Japanese Patent Laid-Open No. 2023-110873 describes that a coupling suppression line is arranged to suppress the coupling capacitance between pads each arranged in a portion where the first structure and the second structure are bonded in a wiring structure that electrically connects an element arranged in the first substrate and an element arranged in the second substrate.

### SUMMARY OF THE INVENTION

To further improve the image quality in the photoelectric conversion device, it is desired to further suppress the coupling capacitance.

Some embodiments of the present invention provide a technique advantageous in suppressing a coupling capacitance.

According to some embodiments, a photoelectric conversion device in which a first semiconductor layer where a first floating diffusion and a second floating diffusion are arranged, a second semiconductor layer, a first wiring structure arranged between the first semiconductor layer and the second semiconductor layer, and a second wiring structure arranged between the first wiring structure and the second semiconductor layer and bonded to the first wiring structure via a plurality of metal pads are stacked, wherein the first floating diffusion is connected to a first transistor arranged in the second semiconductor layer via a first metal pad of the plurality of metal pads, the second floating diffusion is connected to a second transistor arranged in the second semiconductor layer via a second metal pad of the plurality of metal pads, the plurality of metal pads include a third metal pad arranged between the first metal pad and the second metal pad, a conductive pattern extending toward the first semiconductor layer from the third metal pad is arranged in the first wiring structure, the first transistor and the second transistor are arranged in a surface of the second semiconductor layer on an opposite side of a surface thereof facing the first semiconductor layer, and a wiring pattern connecting the first metal pad and the first transistor and a wiring pattern connecting the second metal pad and the second transistor are arranged to extend through the second semiconductor layer, is provided.

Further features of the present invention will become apparent from the following description of exemplary embodiments (with reference to the attached drawings).

### BRIEF DESCRIPTION OF THE DRAWINGS

FIG. 1 is a circuit diagram showing an example of the arrangement of pixels of a photoelectric conversion device according to an embodiment;

FIG. 2 is a plan view showing an example of the arrangement of pixels of the photoelectric conversion device shown in FIG. 1;

FIG. 3 is a sectional view showing an example of the arrangement of pixels of the photoelectric conversion device shown in FIG. 1;

FIGS. 4A and 4B are plan views each showing an example of the arrangement of pixels of the photoelectric conversion device shown in FIG. 1;

FIG. 5 is a plan view showing an example of the arrangement of pixels of the photoelectric conversion device shown in FIG. 1;

FIG. 6 is a sectional view showing an example of the arrangement of pixels of the photoelectric conversion device shown in FIG. 1;

FIG. 7 is a sectional view showing an example of the arrangement of pixels of the photoelectric conversion device shown in FIG. 1;

FIGS. 8A to 8C are plan views showing an example of the arrangement of a pixel region and a peripheral region of the photoelectric conversion device shown in FIG. 1;

FIG. 9 is a sectional view showing the example of the arrangement of the pixel region and the peripheral region of the photoelectric conversion device shown in FIG. 1;

FIG. 10 is a sectional view showing an example of the arrangement of pixels of the photoelectric conversion device shown in FIG. 1;

FIG. 11 is a sectional view showing an example of the arrangement of a pixel region and a peripheral region of the photoelectric conversion device shown in FIG. 1; and

FIG. 12 is a view showing an example of the arrangement of equipment incorporating the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

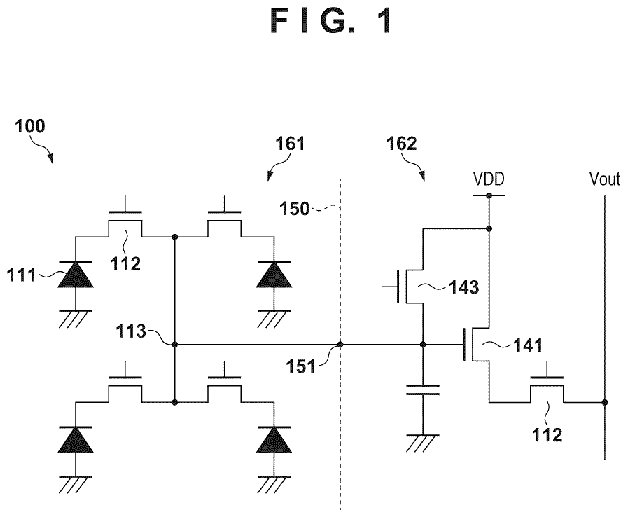

With reference to FIGS. 1 to 11, a photoelectric conversion device according to an embodiment of the present disclosure will be described. The following embodiments are merely examples of the present disclosure and not intended to limit the scope of the invention according to the appended claims.

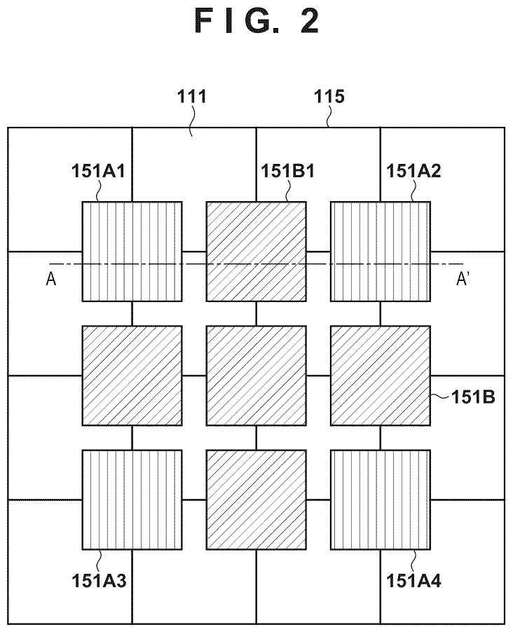

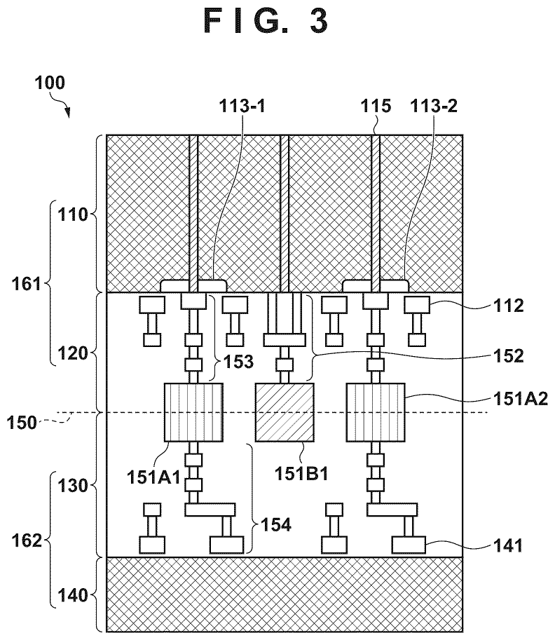

FIG. 1 is a view showing an example of the circuit arrangement of pixels arranged in a photoelectric conversion device 100 according to the embodiment. FIG. 2 is a plan view focusing on metal pads 151 (to be described later) arranged in the pixels. FIG. 3 is a sectional view taken along a line A-A′ in FIG. 2.

The photoelectric conversion device 100 is formed by stacking a substrate 161 and a substrate 162. More specifically, as shown in FIG. 3, in the photoelectric conversion device 100, a semiconductor layer 110, a semiconductor layer 140, a wiring structure 120 arranged between the semiconductor layer 110 and the semiconductor layer 140, and a wiring structure 130 arranged between the wiring structure 120 and the semiconductor layer 140 and bonded to the wiring structure 120 via a plurality of the metal pads 151 are stacked. Here, a combination of the semiconductor layer 110 and the wiring structure 120 located on the semiconductor layer 110 side of a bonding surface 150 between the wiring structure 120 and the wiring structure 130 will be referred to as the substrate 161. A combination of the semiconductor layer 140 and the wiring structure 130 located on the semiconductor layer 140 side of the bonding surface 150 will be referred to as the substrate 162.

In the substrate 161, photodiodes (PDs) 111, transfer transistors 112, and floating diffusions (FDs) 113 are arranged. More specifically, the PDs 111 and the FDs 113 are arranged in the semiconductor layer 110 of the substrate 161. The transfer transistors 112 are arranged across the semiconductor layer 110 and the wiring structure 120 of the substrate 161.

Source follower (SF) transistors 141, selection transistors 142, and reset transistors 143 are arranged in the substrate 162. An output from a pixel including the PD 111 is supplied to an output line Vout via the selection transistor 142. More specifically, the SF transistors 141, the selection transistors 142, and the reset transistors 143 are arranged across the semiconductor layer 140 and the wiring structure 130 of the substrate 162. The output line Vout is arranged in, for example, the wiring structure 130.

In the arrangement shown in FIG. 1, four PDs 111 are connected to one FD 113. However, the number of the PDs connected to one FD 113 may be one, two, three, or five or more. In accordance with the specifications of the photoelectric conversion device 100, an appropriate number of the PDs 111 are connected to one FD 113. Further, a microlens (ML) that condenses light to the PD 111 may be provided on the light incident surface side of the substrate 161. If the ML is provided, different MLs may be provided for the respective PDs 111, or one ML may be shared by two or more PDs 111. In the latter arrangement, it is possible to detect a phase difference by using output signals from the PDs 111 sharing the ML. The FD 113 is connected to the gate of the SF transistor 141 via the metal pad 151 bonding the substrate 161 and the substrate 162. It can also be said that the substrate 161 and the substrate 162 are bonded by metal bonding (MB) via the metal pads 151 arranged in the bonding surface 150 between the wiring structure 120 and the wiring structure 130.

FIG. 2 is a schematic plan view focusing on the metal pads 151. FIG. 2 shows 4×4 PDs 111, and one metal pad 151 is arranged for one FD 113 connected to 2×2 PDs 111 as shown in the circuit diagram of FIG. 1. For example, the metal pad 151 may be arranged in the center of 2×2 PDs 111 as shown in FIG. 2. As shown in FIG. 2, the metal pad 151 connected to the FD 113 is sometimes referred to as a metal pad 151A. In the arrangement shown in FIG. 2, for 4×4 PDs 111, one FD 113 is arranged for every 2×2 PDs 111. Therefore, four metal pads 151A1 to 151A4 corresponding to four FDs 113 are shown. Metal pads 151B not connected to the FDs 113 are arranged between the metal pads 151A1 to 151A4 connected to the FDs 113.

As shown in FIG. 3, the pixel including the PD 111, the transfer transistor 112, and the FD 113 (the PD 111 is not shown in FIG. 3) is isolated by an insulating film of silicon oxide or the like, or a pixel isolation region 115 formed of metal or the like. A description will be given below assuming that one PD 111 corresponds to one pixel. For example, it will be described assuming that four pixels (PDs 111) share one FD 113 in the arrangement described above.

An FD 113-1 shown on the left side in FIG. 3 is connected to a transistor such as the SF transistor 141 arranged in the semiconductor layer 140 via the metal pad 151A1 of the multiple metal pads 151. An FD 113-2 shown on the right side in FIG. 3 is connected to a transistor such as the SF transistor 141 arranged in the semiconductor layer 140 via the metal pad 151A2 of the multiple metal pads 151. As shown in FIG. 1, one metal pad 151A, the SF transistor 141, the selection transistor 142, and the reset transistor 143 are arranged for one FD 113. The FD 113 and the metal pad 151A are connected by a wiring pattern 153 arranged in the wiring structure 120. The metal pad 151A and the SF transistor 141 arranged in the semiconductor layer 140 are connected by a wiring pattern 154 arranged in the wiring structure 130.

As has been described above, the metal pad 151B not connected to the FD 113 is arranged between the metal pads 151A. As shown in FIG. 2, a metal pad 151B1 is arranged between the metal pad 151A1 and the metal pad 151A2. The metal pad 151A1 and the metal pad 151B1 are arranged adjacent to each other, and the metal pad 151A2 and the metal pad 151B1 are arranged adjacent to each other. It can also be said that the metal pad 151B not connected to the FDs 113 is arranged between the metal pads 151A connected to the FDs 113 such that the metal pads 151A connected to the FDs 113 are not adjacent to each other. In this case, a conductive pattern 152 extending toward the semiconductor layer 110 from the metal pad 151B (151B1) not connected to the FD 113 is arranged in the wiring structure 120.

The conductive pattern 152 is arranged between the wiring patterns 153 each connecting the FD 113 and the metal pad 151A. The conductive pattern 152 can be formed simultaneously with the wiring pattern 153. Accordingly, the conductive pattern 152 can be formed in the wiring structure 120 without adding a step for forming the conductive pattern 152. The conductive pattern 152 is arranged at a position closer to the semiconductor layer 110 than the multiple metal pads 151 arranged in the wiring structure 120.

The conductive pattern 152 may be in contact with the semiconductor layer 110. That is, the conductive pattern 152 may be electrically connected to the semiconductor layer 110. For example, a well potential of 0 V or the like may be supplied to the pixel including the PD 111 and the FD 113 arranged in the semiconductor layer 110 via the metal pad 151B and the conductive pattern 152.

A signal output from the FD 113 arranged in the semiconductor layer 110 of the substrate 161 is supplied to the SF transistor 141 or the like arranged in the semiconductor layer 140 of the substrate 162. In this case, the wiring patterns 153 and 154 through which the signal passes are close to those in the adjacent pixel for a long distance in the stacking direction of the substrates 161 and 162. This is assumed to increase the coupling capacitance. Due to the crosstalk via the coupling capacitance between the wiring patterns 153 and 154, for example, a signal passing through given wiring patterns 153 and 154 may be partially superimposed as noise on a signal passing through other wiring patterns. The noise caused by the crosstalk may degrade the quality of an image obtained by the photoelectric conversion device 100. In addition, the metal pad 151 connecting the wiring structure 120 of the substrate 161 and the wiring structure 130 of the substrate 162 can be formed larger than the wiring patterns 153 and 154 and close to the adjacent metal pad 151, and this increases the coupling capacitance.

To address these problems, in this embodiment, the metal pad 151B not connected to the FD 113 is arranged between the metal pads 151A connected to the FDs 113. With this, the coupling capacitance between the adjacent metal pads 151A can be suppressed. Further, the conductive pattern 152 extending from the metal pad 151B toward the semiconductor layer 110 of the substrate 161 is arranged. With this, the coupling capacitance between the wiring patterns 153 respectively connected to the adjacent FDs 113 (and metal pads 151A) can be suppressed. That is, the coupling capacitance generated on the substrate 161 side can also be suppressed. Hence, the quality of an image obtained by the photoelectric conversion device 100 can be improved.

Furthermore, as has been described above, the metal pad 151B and the conductive pattern 152 may function as a supply line for supplying a predetermined potential to the semiconductor layer 110. In this case, the layout efficiency in, for example, the wiring structure 120 of the photoelectric conversion device 100 is improved. However, the present invention is not limited to this, and the metal pad 151B and the conductive pattern 152 may be in a floating state. In that case, the conductive pattern 152 may or may not reach the semiconductor layer 110 from the metal pad 151B. For example, the metal pad 151B may be connected to the output of the SF transistor 141 (between the SF transistor 141 and the selection transistor 142 shown in FIG. 1) whose gate is connected to the metal pad 151A via the wiring pattern 154. With this, the capacitance applied between the FD 113 and the conductive pattern 152 (and the metal pad 151B) can be reduced, thereby reducing the FD capacitance.

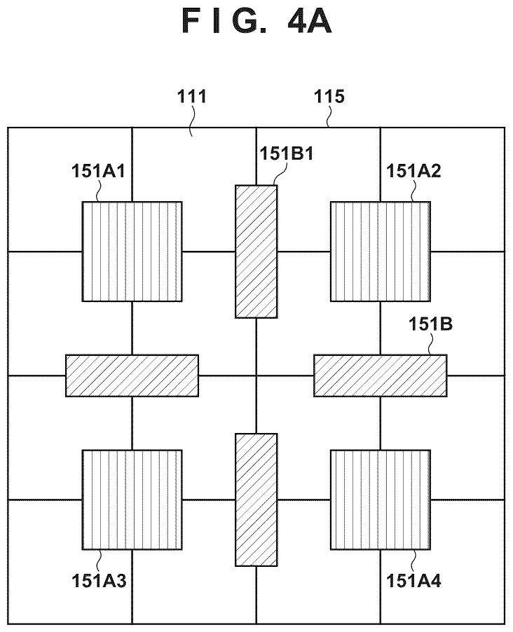

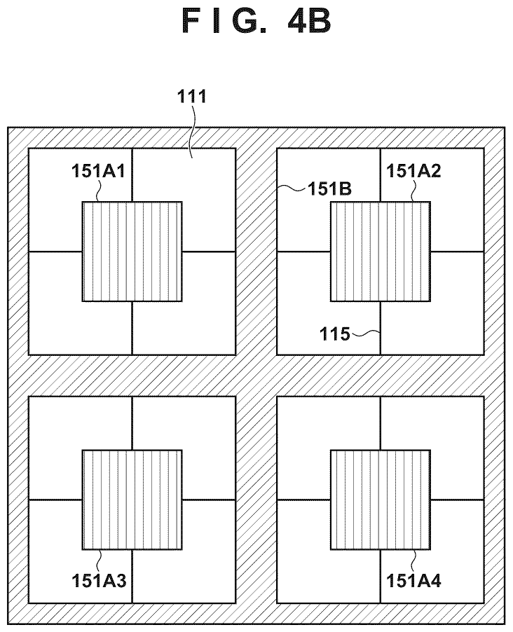

FIGS. 4A and 4B are plan views each showing a modification of the arrangement of the metal pads 151 shown in FIG. 2. In the arrangement shown in FIG. 2, in an orthogonal projection to the bonding surface 150 where the wiring structure 120 and the wiring structure 130 are bonded, the metal pad 151A and the metal pad 151B have the same shape. However, the present invention is not limited to this. As shown in FIG. 4A, the metal pad 151A and the metal pad 151B may have different shapes. For example, in order to prevent a short circuit caused by a foreign object in the manufacturing process, a larger space between the metal pad 151A and the metal pad 151B can suppress the possibility of the short circuit. Therefore, in the orthogonal projection to the bonding surface 150, the length of the metal pad 151B1 in the arranging direction of the metal pad 151A1 and the metal pad 151A2 may be smaller than the length of each of the metal pads 151A1 and 151A2 in the arranging direction of the metal pad 151A1 and the metal pad 151A2. That is, the length of the metal pad 151B in the arranging direction of two metal pads 151A arranged between the two metal pads 151A may be smaller than the length of the metal pad 151A in this direction. In this case, the length of the metal pad 151B1 in a direction crossing the arranging direction of the metal pad 151A1 and the metal pad 151A2 may be equal to or larger than the length of each of the metal pads 151A1 and 151A2 in the direction crossing the arranging direction of the metal pad 151A1 and the metal pad 151A2. That is, the length of the metal pad 151B in the direction crossing the arranging direction of two metal pads 151A may be equal to or larger than the length of the metal pad 151A in this direction. With this, the effect of suppressing the coupling capacitance between two metal pads 151A arranged to sandwich the metal pad 151B can be improved.

Alternatively, for example, as shown in FIG. 4B, the multiple metal pads 151B shown in FIG. 2 or FIG. 4A may be connected and arranged. For example, in the orthogonal projection to the bonding surface 150, the metal pad 151B may be arranged to surround each metal pad 151A. When the multiple metal pads 151B are independently arranged, it is necessary to supply a potential to each metal pad 151B to fix the metal pad 151B (and the conductive pattern 152) at a predetermined potential. On the other hand, in the arrangement shown in FIG. 4B, for example, by supplying a predetermined potential to one point, the potential can be supplied to the metal pad 151B in the entire region. Hence, the layout efficiency of the wiring structure 120 can be improved.

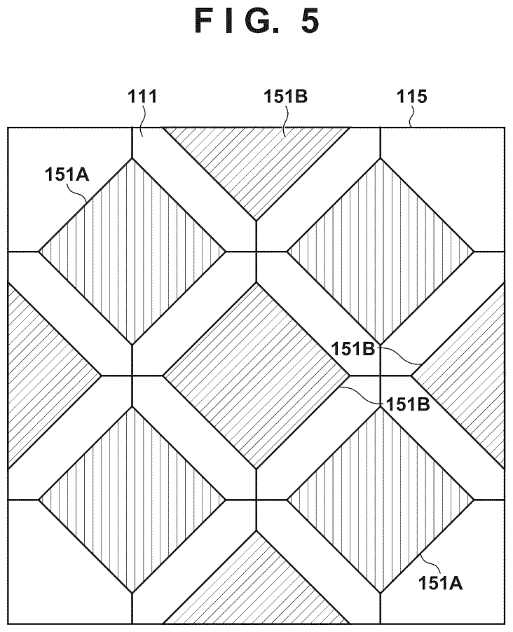

FIG. 5 is a plan view showing a further modification of the arrangement of the metal pads 151. Comparing to the arrangement shown in FIG. 2, the array direction of the metal pads 151 (151A and 151B) is rotated by 45° with respect to the PDs 111. In the arrangement shown in FIG. 5, the above-described effect can also be obtained. Further, the arrangement shown in FIG. 5 can reduce the arrangement number of the metal pads 151B as compared to the arrangement shown in FIG. 2. Hence, the arrangement shown in FIG. 5 is advantageous in miniaturization of pixels in the photoelectric conversion device 100.

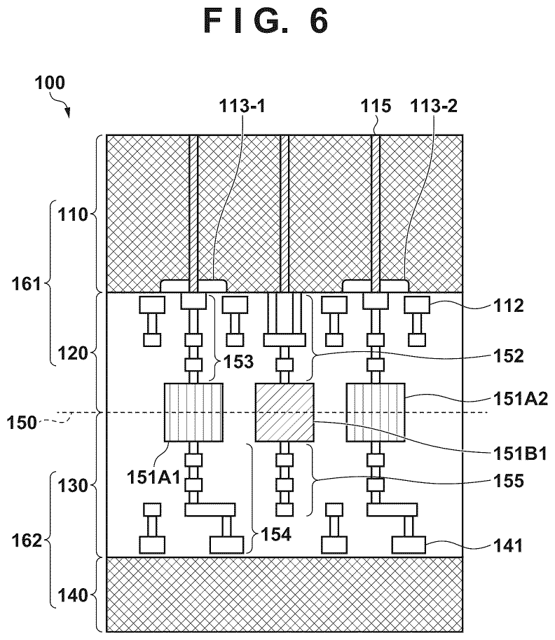

FIG. 6 is a view showing a modification of the sectional view shown in FIG. 3. As compared to the arrangement shown in FIG. 3, in the arrangement shown in FIG. 6, a conductive pattern 155 extending from the metal pad 151B toward the semiconductor layer 140 is arranged in the wiring structure 130. Since the remaining arrangement may similar to the arrangement described above, the conductive pattern 155 will be mainly described below.

The conductive pattern 155 is arranged between the wiring patterns 154 each connecting the metal pad 151A and a transistor such as the SF transistor 141 arranged in the semiconductor layer 140. The conductive pattern 155 can be formed simultaneously with the wiring pattern 154. Accordingly, the conductive pattern 155 can be formed in the wiring structure 130 without adding a step for forming the conductive pattern 155. The conductive pattern 155 is arranged at a position closer to the semiconductor layer 140 than the multiple metal pads 151 arranged in the wiring structure 130.

The conductive pattern 155 extending from the metal pad 151B toward the semiconductor layer 140 of the substrate 162 is arranged. With this, the coupling capacitance between the wiring patterns 154 respectively connected to the adjacent FDs 113 (and metal pads 151A) can be suppressed. That is, not only the coupling capacitance generated on the substrate 161 side but also the coupling capacitance generated on the substrate 162 side can be suppressed. Hence, the quality of an image obtained by the photoelectric conversion device 100 can be improved.

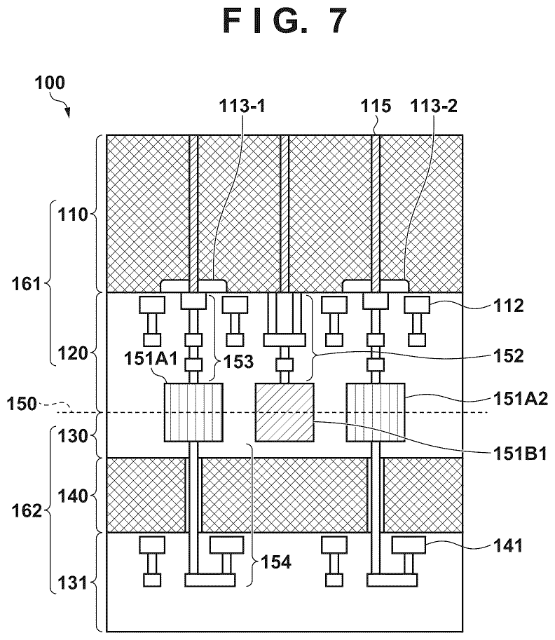

With reference to FIGS. 7 to 10, further modifications of the photoelectric conversion device 100 described above will be described. The arrangement different from the above-described embodiment will be described below in detail, and the arrangement that may be similar to the above-described embodiment will not be described, as appropriate.

FIG. 7 is a view showing a modification of the sectional view shown in FIG. 3. In each embodiment described above, elements such as the SF transistor 141 arranged in the semiconductor layer 140 are arranged in the surface of the semiconductor layer 140 facing the semiconductor layer 110. On the other hand, in the arrangement shown in FIG. 7, elements such as the SF transistor 141 arranged in the semiconductor layer 140 are arranged in the surface of the semiconductor layer 140 on the opposite side of the surface thereof facing the semiconductor layer 110. Therefore, the wiring pattern 154 connecting the metal pad 151A and the transistor such as the SF transistor 141 arranged in the semiconductor layer 140 is arranged to extend through the semiconductor layer 140. Accordingly, a through hole for allowing the wiring pattern 154 to pass therethrough is arranged in the semiconductor layer 140. Between the through hole provided in the semiconductor layer 140 and the wiring pattern 154, an insulating film using silicon oxide or the like or a barrier metal film using titanium or the like can be arranged. The wiring pattern 154 can be arranged not only in the wiring structure 130 between the wiring structure 120 (bonding surface 150) and the semiconductor layer 140 but also in a wiring structure 131 in contact with the surface of the semiconductor layer 140 on the opposite side of the surface thereof in contact with the wiring structure 130.

In the arrangement shown in FIG. 3, an insulator forming the wiring structure 130 is arranged between the adjacent wiring patterns 154. On the other hand, in the arrangement shown in FIG. 7, the adjacent wiring patterns 154 arranged in parallel are partially surrounded by the semiconductor layer 140. With this, the semiconductor layer 140 functions as a shield that suppresses coupling between the wiring patterns 154. Hence, the coupling capacitance between the wiring patterns 154 respectively connected to the adjacent FDs 113 (and metal pads 151A) can be suppressed. That is, coupling generated on the substrate 162 side can be suppressed.

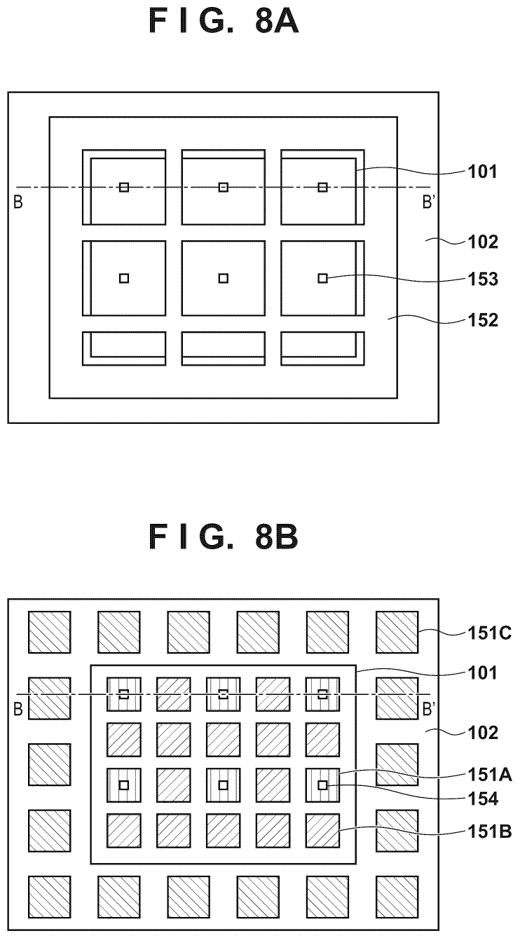

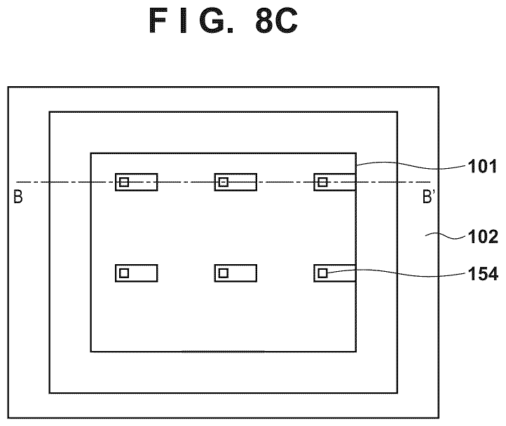

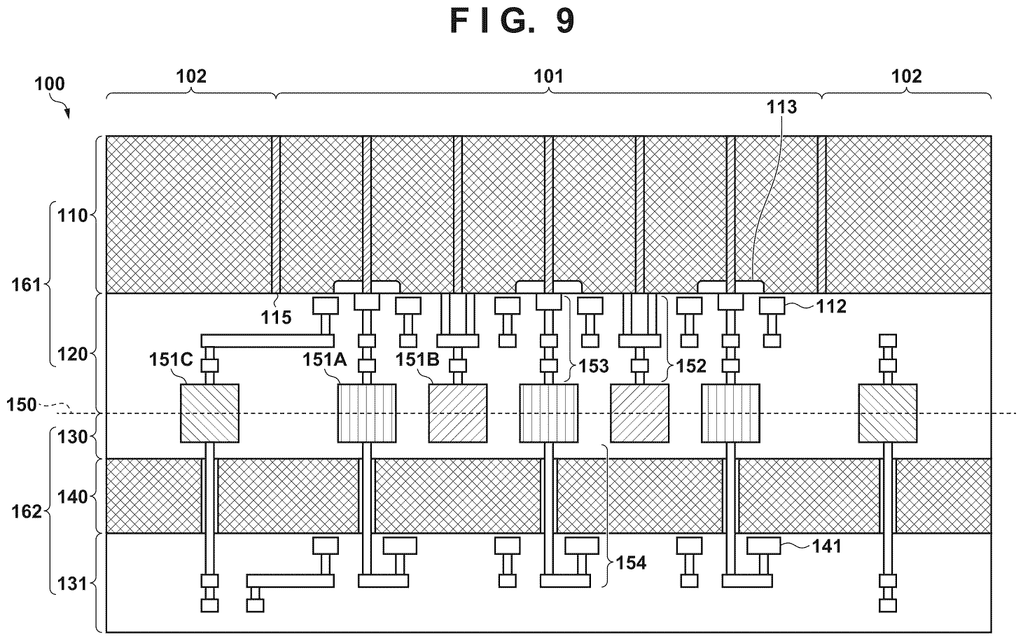

FIGS. 8A to 8C are plan views showing an example of the arrangement of a pixel array 101 and a peripheral region 102 of the photoelectric conversion device 100 in this embodiment. FIG. 8A shows an example of the arrangement of the wiring pattern 153 and the conductive pattern 152 arranged in the wiring structure 120 of the substrate 161. FIG. 8B shows an example of the arrangement of the metal pads 151 each bonding the wiring structure 120 and the wiring structure 130. FIG. 8B also shows the position where the wiring pattern 154 arranged in the wiring structure 130 of the substrate 162 contacts the metal pad 151A (or the position where the wiring pattern 154 passes through the semiconductor layer 140). FIG. 8C shows a pattern of the wiring patterns 154 which extends through the semiconductor layer 140, and a pattern thereof that connects the pattern extending through the semiconductor layer 140 and the gate of the SF transistor 141. FIG. 9 is a sectional view taken along a line B-B′ shown in FIG. 8A.

The conductive pattern 152 may be arranged so as to at least partially surround the wiring pattern 153 connecting the FD 113 and the metal pad 151A. As shown in FIG. 8A, the conductive pattern 152 may be arranged to surround the respective wiring patterns 153. With this arrangement, it is possible to surround coupling between the adjacent wiring patterns 153 in the vertical direction and the horizontal direction shown in FIG. 8A. The arrangement relationship between the conductive pattern 152 and the wiring pattern 153 shown in FIG. 8A is applicable not only to the arrangement shown in FIG. 7 but also to each arrangement described above.

As shown in FIGS. 8B and 9, a metal pad 151C may be arranged in the peripheral region 102. The metal pad 151C may be larger than the metal pads 151A and 151B. The metal pad 151C connects the wiring structure 120 of the substrate 161 and the wiring structure 130 of the substrate 162. As shown in FIG. 9, the metal pad 151C may be connected to the wiring patterns 153 and 154 arranged in the wiring structures 120 and 130, respectively, and function as a conductive path between various elements arranged in the semiconductor layers 110 and 140.

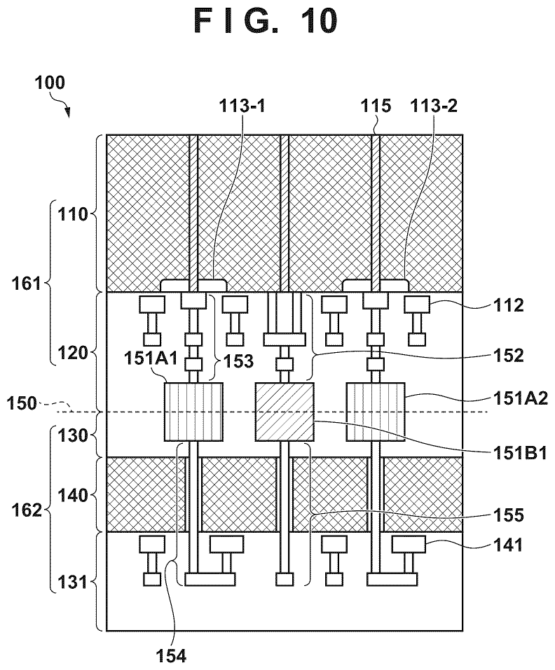

FIG. 10 is a view showing a modification of the sectional view shown in FIG. 7. As shown in FIG. 10, the conductive pattern 155 extending toward the semiconductor layer 140 from the metal pad 151B not connected to the FD 113 may extend through the semiconductor layer 140. Similar to the arrangement shown in FIG. 6, this arrangement can suppress the coupling capacitance between the wiring patterns 154 respectively connected to the adjacent FDs 113 (and metal pads 151A), thereby suppressing the coupling capacitance generated on the substrate 162 side.

Similar to the relationship between the conductive pattern 152 and the wiring pattern 153 as shown in FIG. 8A, the conductive pattern 155 may be arranged to at least partially surround the wiring pattern 154 connecting the metal pad 151A and the transistor such as the SF transistor 141 arranged in the semiconductor layer 140. This can suppress coupling between the adjacent wiring patterns 154. For example, the portions of the conductive pattern 155 respectively arranged in the wiring structures 130 and 131 are arranged to surround the respective wiring patterns 154.

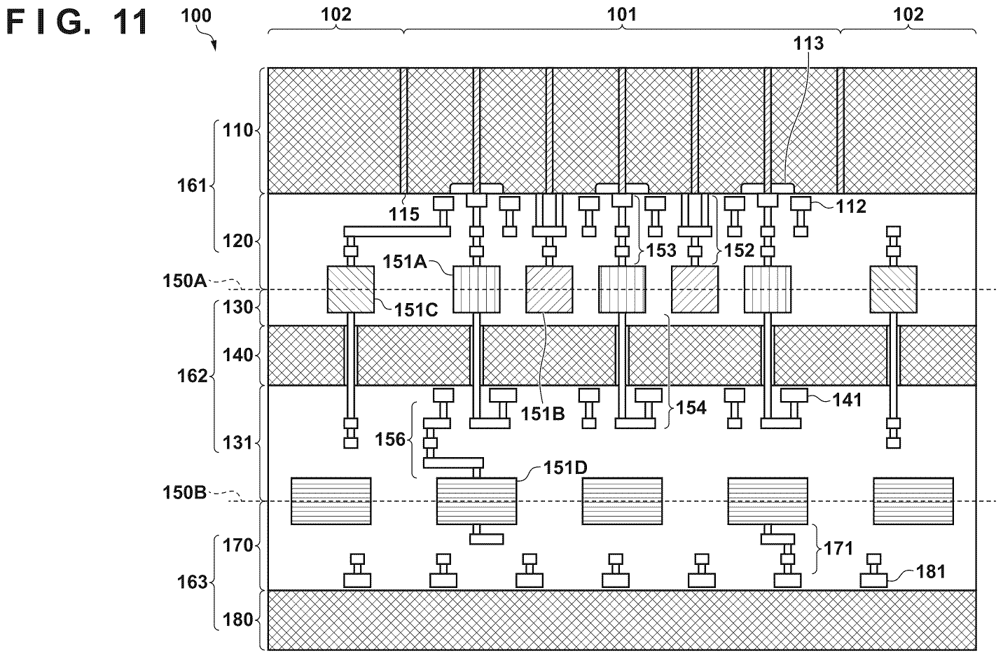

FIG. 11 shows an arrangement example in which a substrate 163 including a semiconductor layer 180 and a wiring structure 170 is further stacked on the arrangement shown in FIG. 9. In the arrangement shown in FIG. 11, the semiconductor layer 140 is arranged between the semiconductor layer 110 and the semiconductor layer 180. The wiring structure 131 of the substrate 162 and the wiring structure 170 of the substrate 163 are bonded via multiple metal pads 151D, like bonding between the wiring structure 120 of the substrate 161 and the wiring structure 130 of the substrate 162. Elements 181 such as transistors are arranged in the surface of the semiconductor layer 180 facing the semiconductor layer 140. For example, the element 181 may receive a signal output from the FD 113 arranged in the semiconductor layer 110 and perform signal processing or the like. For example, a wiring pattern 156 arranged in the wiring structure 131 and a wiring pattern 171 arranged in the wiring structure 170 shown in FIG. 11 may be used as the output line Vout shown in FIG. 1. In this case, the signal output from the FD 113 can be processed by the element 181 arranged in the semiconductor layer 180. In this manner, by increasing the number of substrates (semiconductor layers), the functionality of the photoelectric conversion device 100 can be improved.

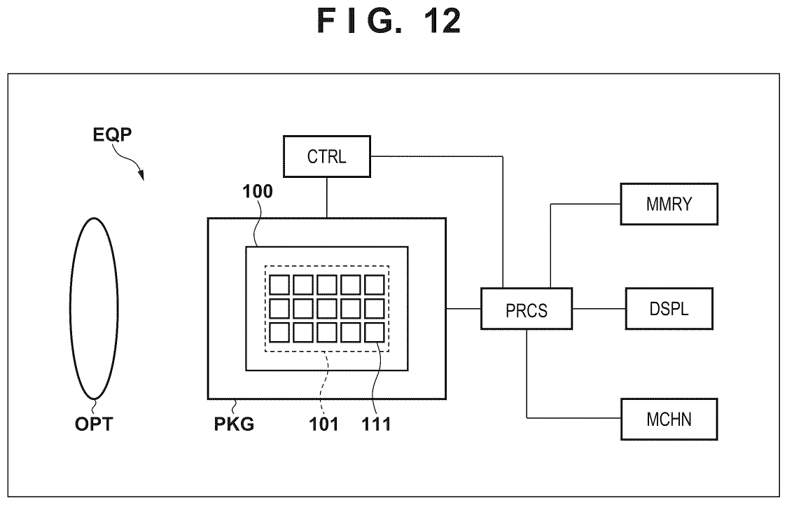

An application example of the photoelectric conversion device 100 according to the embodiment described above will be described below. FIG. 12 is a schematic view of electronic equipment EQP incorporating the photoelectric conversion device 100. As shown in FIG. 12, the photoelectric conversion device 100 is contained in a semiconductor package PKG. The semiconductor package PKG can include a base to which the photoelectric conversion device 100 is fixed, a lid such as glass facing the photoelectric conversion device 100, and a conductive connecting member such as a bonding wire or bump used to connect the terminal arranged in the base to a terminal arranged in the photoelectric conversion device 100. The equipment EQP may further include at least one of a control device CTRL, a processing device PRCS, a display device DSPL, and a storage device MMRY.

An optical system OPT is a system for forming an image on the pixel array 101, and can be, for example, a lens, a shutter, and a mirror. The control device CTRL is a device for controlling the operation of the photoelectric conversion device 100, and can be, for example, a semiconductor device such as an ASIC. The processing device PRCS processes the signal output from the photoelectric conversion device 100, and can be, for example, a semiconductor device such as a CPU or an ASIC. The display device DSPL can be an EL display device or a liquid crystal display device that displays data obtained by the photoelectric conversion device 100. The storage device MMRY is a magnetic device or a semiconductor device for storing data obtained by the photoelectric conversion device 100. The storage device MMRY can be a volatile memory such as an SRAM or a DRAM, or a nonvolatile memory such as a flash memory or a hard disk drive. A mechanical device MCHN can include a moving or propulsion unit such as a motor or an engine. For example, the mechanical device MCHN drives the components of the optical system OPT for zooming, focusing, and shutter operations. In the equipment EQP, data output from the photoelectric conversion device 100 is displayed on the display device DSPL, or transmitted to an external device by a communication device (not shown) included in the equipment EQP. Hence, the equipment EQP may include the storage device MMRY and the processing device PRCS.

The equipment EQP incorporating the photoelectric conversion device 100 is also applicable as a surveillance camera or an onboard camera mounted in transportation equipment such as an automobile, a railroad car, a ship, an airplane, or an industrial robot. In addition, the equipment EQP incorporating the photoelectric conversion device 100 is not limited to transportation equipment but is also applicable to equipment that widely uses object recognition, such as an intelligent transportation system (ITS).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-204914, filed Dec. 4, 2023, which is hereby incorporated by reference herein in its entirety.

What is claimed is:

1. A photoelectric conversion device in which a first semiconductor layer where a first floating diffusion and a second floating diffusion are arranged, a second semiconductor layer, a first wiring structure arranged between the first semiconductor layer and the second semiconductor layer, and a second wiring structure arranged between the first wiring structure and the second semiconductor layer and bonded to the first wiring structure via a plurality of metal pads are stacked, wherein
the first floating diffusion is connected to a first transistor arranged in the second semiconductor layer via a first metal pad of the plurality of metal pads,
the second floating diffusion is connected to a second transistor arranged in the second semiconductor layer via a second metal pad of the plurality of metal pads,
the plurality of metal pads include a third metal pad arranged between the first metal pad and the second metal pad,
a conductive pattern extending toward the first semiconductor layer from the third metal pad is arranged in the first wiring structure,
the first transistor and the second transistor are arranged in a surface of the second semiconductor layer on an opposite side of a surface thereof facing the first semiconductor layer, and
a wiring pattern connecting the first metal pad and the first transistor and a wiring pattern connecting the second metal pad and the second transistor are arranged to extend through the second semiconductor layer.

2. The device according to claim 1, wherein the conductive pattern is in contact with the first semiconductor layer.

3. The device according to claim 2, wherein a well potential is supplied, via the third metal pad and the conductive pattern, to a pixel including the first floating diffusion and the second floating diffusion arranged in the first semiconductor layer.

4. The device according to claim 1, wherein the third metal pad is in a floating state.

5. The device according to claim 1, wherein
the first metal pad is connected to a gate of the first transistor via a wiring pattern, and
the third metal pad is connected to an output of the first transistor.

6. The device according to claim 1, wherein
the first metal pad and the third metal pad are arranged adjacent to each other, and
the second metal pad and the third metal pad are arranged adjacent to each other.

7. The device according to claim 1, wherein the conductive pattern is arranged at a position closer to the first semiconductor layer than the plurality of metal pads.

8. The device according to claim 1, wherein the conductive pattern is arranged to at least partially surround a wiring pattern connecting the first floating diffusion and the first metal pad.

9. The device according to claim 1, wherein
the conductive pattern is a first conductive pattern, and
a second conductive pattern extending toward the second semiconductor layer from the third metal pad is arranged in the second wiring structure.

10. The device according to claim 9, wherein the second conductive pattern is arranged at a position closer to the second semiconductor layer than the plurality of metal pads.

11. The device according to claim 9, wherein the second conductive pattern is arranged to at least partially surround a wiring pattern connecting the first metal pad and the first transistor.

12. The device according to claim 9, wherein
the second conductive pattern extends through the second semiconductor layer.

13. The device according to claim 1, wherein in an orthogonal projection to a bonding surface where the first wiring structure and the second wiring structure are bonded, the first metal pad, the second metal pad, and the third metal pad have the same shape.

14. The device according to claim 1, wherein in an orthogonal projection to a bonding surface where the first wiring structure and the second wiring structure are bonded, a length of the third metal pad in an arranging direction of the first metal pad and the second metal pad is smaller than a length of each of the first metal pad and the second metal pad in the arranging direction.

15. The device according to claim 14, wherein the length of the third metal pad in a direction crossing the arranging direction is not less than the length of each of the first metal pad and the second metal pad in the crossing direction.

16. The device according to claim 1, wherein in an orthogonal projection to a bonding surface where the first wiring structure and the second wiring structure are bonded, the third metal pad is arranged to surround each of the first metal pad and the second metal pad.

17. The device according to claim 1, wherein
a third semiconductor layer is further stacked,
the second semiconductor layer is arranged between the first semiconductor layer and the third semiconductor layer, and
an element configured to receive a signal output from the first floating diffusion is arranged in a surface of the third semiconductor layer facing the second semiconductor layer.

18. Equipment comprising:
the photoelectric conversion device according to claim 1; and
a processing device configured to process a signal output from the photoelectric conversion device.
